(19) United States
(12) Patent Application Publication
(10) Pub. No.: US 2015/0346443 A1
(43) Pub. Date: Dec. 3, 2015

(54) SEMICONDUCTOR OPTICAL INTEGRATED CIRCUIT

(71) Applicant: V TECHNOLOGY CO., LTD., Kanagawa (JP)

(72) Inventor: Michinobu Mizumura, Kanagawa (JP)

(73) Assignee: V TECHNOLOGY CO., LTD., Kanagawa (JP)

(21) Appl. No.: 14/654,593

(22) PCT Filed: Dec. 10, 2013
(86) PCT No.: PCT/JP2013/083031

§ 371 Date: Jun. 22, 2015

(30) Foreign Application Priority Data
Dec. 26, 2012 (JP) 2012-283727

(51) Int. Cl. G02B 6/42; H01S 5/32; G02B 6/122

(52) U.S. Cl. CPC G02B 6/4298; G02B 6/122; H01S 5/32

(57) ABSTRACT

The semiconductor optical integrated circuit has a semiconductor substrate; a pn junction part formed in the semiconductor substrate so as to continuously extend along a signal transmission route, a light emitting part formed on a part of the pn junction part; and an optical waveguide part formed continuous to the light emitting part on the pn junction part. The light emitting part supplies a drive current to the pn junction part to generate an optical signal from the pn junction part, and the optical waveguide part transmits the optical signal while amplifying the optical signal by an amplification current supplied to the pn junction part.

### CROSS-REFERENCE TO RELATED APPLICATIONS

This application claims the benefit of International Application PCT/JP2013/083031, filed Dec. 10, 2013 and Japanese Patent Application JP2012-283727, filed Dec. 26, 2012, both of which are incorporated herein by reference in their entirety.

### TECHNICAL FIELD

The present invention generally relates to a semiconductor optical integrated circuit in which an optical waveguide is formed in a semiconductor substrate.

### BACKGROUND ART

A semiconductor integrated circuit in which electric wiring is formed in a semiconductor substrate (semiconductor chip) to transmit an electric power and an electrical signal (digital signal) involves signal attenuation generated by the presence of electric resistance in the electric wiring and an induction noise or crosstalk generated by an electric field leaked from wiring parallel to the electric wiring. An optical integrated circuit (optical waveguide module) in which an optical waveguide is formed on a substrate to transmit a signal by light has been proposed (for example, see the following Patent Literature 1).

### RELATED ART LITERATURE

### Patent Literature

Patent Literature 1: Japanese Patent Application Publication No. 2012-78609

### SUMMARY OF THE INVENTION

The optical integrated circuit is required to efficiently perform optical coupling of a light emitting element or a light receiving element packaged in a substrate and an optical waveguide formed on the substrate. In the conventional art, for this optical coupling of the light emitting element or the light receiving element, and the optical waveguide, an optical coupler has been used. This optical coupler requires a light deflection element such as a mirror, a prism, or a diffraction grating, and a light condensing element such as a lens, and in order to obtain high optical coupling efficiency, a processing technique and a positioning technique with high accuracy are required to form the optical coupler. Thus, the optical coupler has not been put in practical use yet at present.

Moreover, it is required that an optical waveguide which is a signal transmission line or an optical coupler is formed in a substrate, and a light emitting element or a light receiving element besides the optical waveguide is packaged on the substrate. Thus, it becomes difficult to integrate circuit components in order to obtain a high-functional circuit.

An example of one or more embodiments of the present invention is to configure a semiconductor optical integrated circuit in which a light emitting part (or a light receiving part) and an optical waveguide part are formed in a semiconductor substrate without boundary. Specifically, the one or more embodiments of the present invention achieve high optical coupling efficiency without using an optical coupler by eliminating a boundary between the light emitting part (or the light receiving part) and the optical waveguide part and to make it possible to highly integrate the circuit components, and the like.

One or more embodiments of the semiconductor optical integrated circuit according to the present invention include at least the following components.

The semiconductor optical integrated circuit includes: a semiconductor substrate; a pn junction part formed in the semiconductor substrate so as to continuously extend along a signal transmission route; a light emitting part formed on a part of the pn junction part; and an optical waveguide part formed continuous to the light emitting part on the pn junction part. The light emitting part supplies a drive current to the pn junction part to generate an optical signal from the pn junction part, and the optical waveguide part transmits the optical signal while amplifying the optical signal by an amplification current supplied to the pn junction part.

### Advantageous Effects of Invention

In the semiconductor optical integrated circuit according to one or more embodiments of the present invention, the pn junction part having a light emitting function or a light amplifying function is formed by supplying a current to the semiconductor substrate, and this pn junction part is continuously extended along the signal transmission route. Then, a part on this pn junction part is formed into the light emitting part, and a part continuous to this light emitting part on the pn junction part is formed into the optical waveguide part. With such configuration, an optical signal generated by light emitting at the light emitting part is transferred to the optical waveguide part without boundary and is transmitted along the optical waveguide part. The light emitting part supplies a drive current to the pn junction part to generate an optical signal from the pn junction part, and the optical waveguide part transmits the optical signal while amplifying the optical signal by an amplification current supplied to the pn junction part.

In the semiconductor optical integrated circuit having such characteristics, high optical coupling efficiency can be achieved without using an optical coupler by forming a light emitting part and an optical waveguide part in the semiconductor substrate without boundary. Moreover, high integration of circuit components can be achieved by forming a part of the pn junction part formed in the semiconductor substrate into a light emitting part and forming the other part into an optical waveguide part. As in the light emitting part, the light receiving part can be formed without boundary with the optical waveguide part.

### BRIEF DESCRIPTION OF THE DRAWINGS

FIG. 1 shows explanatory views showing the semiconductor optical integrated circuit according to one or more embodiments of the present invention. FIG. 1(a) shows a cross section along the signal transmission route, and FIG. 1(b) shows an X-X cross-sectional view of FIG. 1(a).

FIG. 2 shows explanatory views showing an example of a method for forming the semiconductor optical integrated circuit according to one or more embodiments of the present invention.

### DETAILED DESCRIPTION

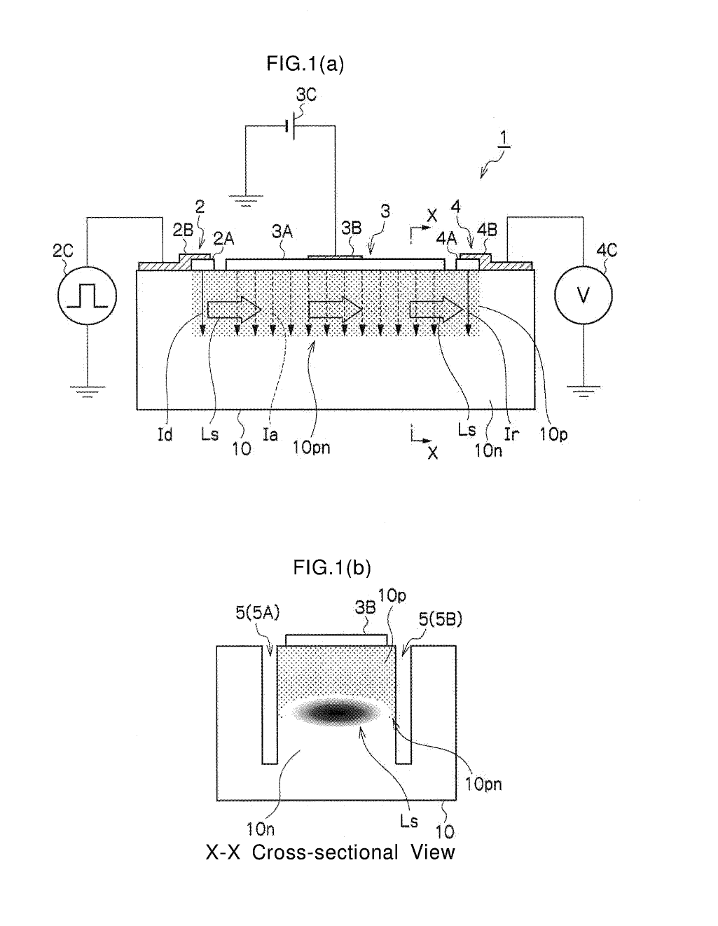

One or more embodiments of the present invention are described below with reference to the drawings. FIG. 1 shows explanatory views showing the semiconductor optical integrated circuit according to one or more embodiments of the present invention. FIG. 1(a) shows a cross section along the signal transmission route, and FIG. 1(b) shows an X-X cross-sectional view of FIG. 1(a).

A semiconductor optical integrated circuit 1 includes a light emitting part 2 and an optical waveguide part 3 on a pn junction part 10pn formed in a semiconductor substrate 10. Although the light emitting part 2, the optical waveguide part 3, and the light receiving part 4 are provided on the pn junction part 10pn in the example shown in FIG. 1, the light emitting part 2 and the optical waveguide part 3 may be combined, and the optical waveguide part 3 and the light receiving part 4 may be combined.

The pn junction part 10pn formed in the semiconductor substrate 10 is continuously extended along the signal transmission route, the light emitting part 2 is formed in a part on the pn junction part 10pn, and the optical waveguide part 3 is formed in another part continuous to the light emitting part 2 on the pn junction part 10pn. In the example shown in FIG. 1, the light emitting part 2 is provided on one end side on the extended pn junction part 10pn, and the light receiving part 4 is provided on the other end side on the pn junction part 10pn. Accordingly, the light emitting part 2, the optical waveguide part 3, and the light receiving part 4 are formed on the continuously extended pn junction part 10pn without boundary. A layer on a series of the pn junction part 10pn is a semiconductor layer with the same refractive index.

In the light emitting part 2, a light emitting function is obtained by supplying a current to the pn junction part 10pn, and in the optical waveguide part 3, a light amplifying function is obtained by supplying a current to the pn junction part 10pn. Moreover, in the light receiving part 4, the pn junction part 10pn can obtain a receive current by the photoelectric conversion function. In order to obtain such function, the pn junction part 10pn is a semiconductor boundary part in which dressed photons are generated by the anneal treatment in the optical assist state. Such pn junction part 10pn can be obtained by subjecting a second semiconductor layer (p-type semiconductor layer) 10p, which is obtained by doping a first semiconductor layer (n-type semiconductor layer) 10n in the semiconductor substrate 10 with an impurity at high concentration, to an anneal treatment while irradiating the second semiconductor layer with light.

Specifically, an Si substrate is used as the semiconductor substrate 10, and an n-type semiconductor layer obtained by doping the semiconductor substrate 10 with a Group 15 element (nitrogen (N), phosphorus (P), arsenic (As), antimony (Sb), or the like) is used as the first semiconductor layer 10n. Then, a p-type semiconductor layer obtained by doping the first semiconductor layer 10n with a Group 13 element (boron (B), aluminum (Al), gallium (Ga), indium (In), or thallium (TI)) as an impurity is used as the second semiconductor layer 10p.

The structures of the respective parts in the semiconductor optical integrated circuit 1 are specifically described. The light emitting part 2 includes a light emitting electrode 2A formed on the pn junction part 10pn (second semiconductor layer 10p). A wiring electrode 2B is connected to the light emitting electrode 2A, and a signal transmission source 2C is connected to this wiring electrode 2B. In the light emitting part 2 which causes an optical signal Ls to be generated, a drive current Id is supplied from the light emitting electrode 2A to the pn junction part 10pn by a drive voltage of the signal transmission source 2C.

The optical waveguide part 3 includes an optical waveguide electrode 3A formed on the pn junction part 10pn (second semiconductor layer 10p). A wiring electrode 3B is connected to the optical waveguide electrode 3A, and a bias power supply 3C is connected to this wiring electrode 3B. In the optical waveguide part 3, an amplification current Ia is supplied from the optical waveguide electrode 3A to the pn junction part 10pn by a bias voltage of the bias power supply 3C, thereby transmitting an optical signal Ls while amplifying.

The light receiving part 4 includes a light receiving electrode 4A formed on the pn junction part 10pn (second semiconductor layer 10p). A wiring electrode 4B is connected to the light receiving electrode 4A, and a signal receiver 4C is connected to this wiring electrode 4B. In the light receiving part 4, a light receiving signal current Ir is generated by the photoelectric conversion function of the pn junction part 10pn which receives light as the optical signal Ls, and the signal receiver 4C detects a change in voltage according to this light receiving signal current Ir as a light receiving signal.

A pair of isolations 5 (5A and 5B) along the signal transmission direction is provided in the semiconductor substrate 10 so as to sandwich the light emitting part 2, the optical waveguide part 3, and the light receiving part 4. The isolations 5 prevent scattering of optical energy in the direction which intersects with the signal transmission direction and can be formed by grooves subjected to dry-etching processing. By providing such isolations 5, crosstalk in optical signal transmission and a loss in transmission can be suppressed.

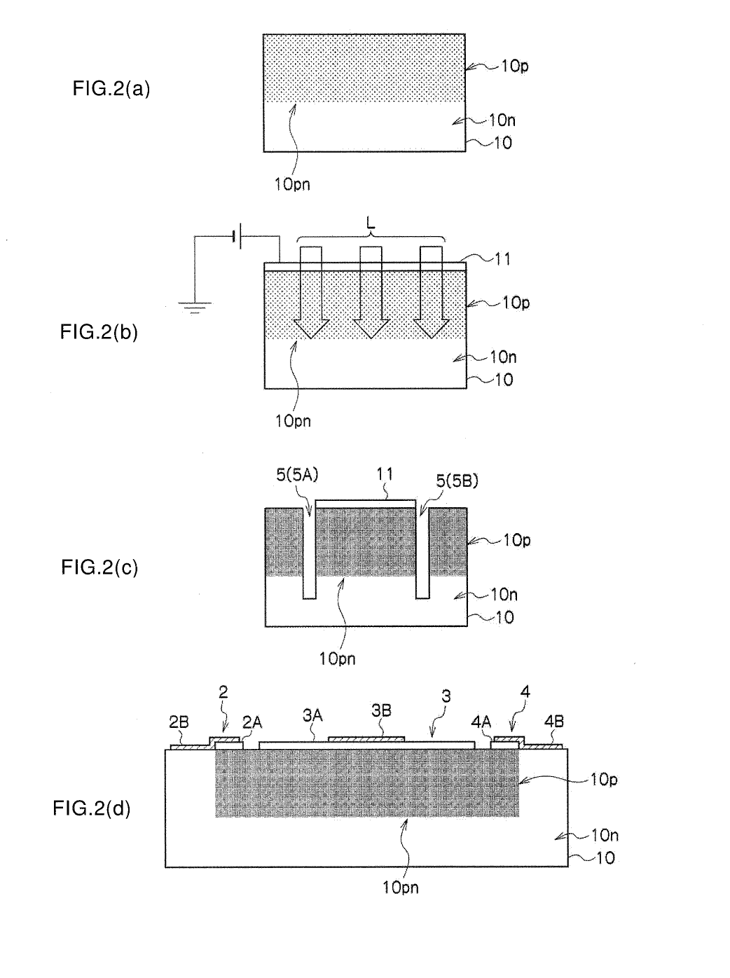

FIG. 2 shows explanatory views showing an example of a method for forming the semiconductor optical integrated circuit according to one or more embodiments of the present invention. First, a first semiconductor layer 10n obtained by doping a semiconductor substrate (Si substrate) 10 with a first substance which is a Group 15 element selected from, for example, arsenic (As), phosphorus (P), and antimony (Sb) is formed. In this case, the first semiconductor layer 10n is an n-type semiconductor layer. Subsequently, as shown in FIG. 2(a), a second semiconductor layer (p-type semiconductor layer) 10p is formed by doping the surface layer with an impurity which is a Group 13 element selected from, for example, boron (B), aluminum (Al), and gallium (Ga) at high concentration.

Then, as shown in FIG. 2(b), a transparent electrode (ITO or the like) 11 is formed on the second semiconductor layer 10p, and thereafter, a forward voltage is applied via the transparent electrode 11 to diffuse the impurity (for example, the impurity selected from boron (B), aluminum (Al), and gallium (Ga)) in the second semiconductor layer 10p by the anneal treatment caused by Joule heat of a current flowing in the pn junction part 10pn. Moreover, dressed photons are generated in the vicinity of the pn junction part 10pn by irradiating the pn junction part 10pn in the stage of this anneal treatment.

The Si substrate itself is an indirect transition semiconductor and has low light emitting efficiency and cannot obtain useful light emission merely by forming a pn junction part. However, the Si substrate is subjected to annealing in the optical assist state to generate dressed photons in the vicinity of the pn junction part 10pn and change Si which is an indirect transmission-type semiconductor to as if it is a direct transition-type semiconductor, thereby achieving high-efficiency, high-output pn junction-type light emission (photoelectric conversion). In order to obtain such pn junction-type light emission (photoelectric conversion), doping with an impurity which is a Group 13 element such as boron (B) at high concentration is performed in formation of the second semiconductor layer 10p. An example of impurity doping conditions (in the case of boron (B)) at the time of the doping is such that a dose density is 5*10¹³/cm², acceleration energy at the time of the injection is 700 keV, and a wavelength of light L with which the irradiation is performed in the stage of the annealing is a desired wavelength band.

Subsequently, as shown in FIG. 2(c), the above-mentioned isolations 5 (5A and 5B) are formed. In order to form the isolations 5, for example, a pair of grooves along the signal transmission line is formed by subjecting the semiconductor substrate 10 to a dry-etching treatment or the like.

Thereafter, as shown in FIG. 2(d), the transparent electrode 11 is divided by insulation through an etching treatment or the like to form a light emitting electrode 2A of the light emitting part 2, an optical waveguide electrode 3A of the an optical waveguide part 3, and a light receiving electrode 4A of the light receiving part 4. Thus, the wiring electrodes 2B, 3B, and 4B are formed on the light emitting electrode 2A, the optical waveguide electrode 3A, and the light receiving electrode 4A, respectively. By connecting a signal transmission source 2C, a bias power supply 3C, and a signal receiver 4C to the wiring electrodes 2B, 3B, and 4B, respectively, the semiconductor optical integrated circuit 1 shown in FIG. 1(a) can be formed.

The semiconductor optical integrated circuit 1 formed as described above can lead the optical signal Ls generated in the light emitting part 2 to the optical waveguide part 3 without boundary and can lead it to the light receiving part 4 by transmitting it while amplifying it in the optical waveguide part 3. Accordingly, the optical coupling efficiency at the time when the optical signal Ls is transferred from light emitting part 2 to the optical waveguide part 3 and the optical coupling efficiency at the time when the optical signal Ls is transferred from the optical waveguide part 3 to the light receiving part 4 can be close to approximately 100%, and a loss in transmission of optical coupling can be reduced as much as possible.

Moreover, the light emitting part 2 and the light receiving part 4 can be set within the width of the optical waveguide part 3 sandwiched between a pair of the isolations 5. Thus, high circuit integration in the semiconductor substrate 10 can be achieved.

While one or more embodiments of the present invention are described in detail above with reference to the drawings, the specific configuration of the present invention is not limited to the embodiment, and the present invention encompasses various modifications in design without departing from the subject matter of the present invention.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### EXPLANATION OF REFERENCE NUMERALS

1: semiconductor optical integrated circuit, 2: light emitting part, 3: optical waveguide part, 4: light receiving part,

10: semiconductor substrate, 10n: first semiconductor layer, 10p: second semiconductor layer,

10pn: pn junction part,

2A: light emitting electrode, 3A: optical waveguide electrode, 4A: light receiving electrode,

2B, 3B, 4B: wiring electrode,

2C: signal transmission source, 3C: bias power supply, 4C: signal receiver

1. A semiconductor optical integrated circuit comprising:
a semiconductor substrate;
a pn junction part formed in the semiconductor substrate so as to continuously extend along a signal transmission route;
a light emitting part formed on a part of the pn junction part; and
an optical waveguide part formed continuous to the light emitting part on the pn junction part,
wherein the light emitting part supplies a drive current to the pn junction part to generate an optical signal from the pn junction part, and
the optical waveguide part transmits the optical signal while amplifying the optical signal by an amplification current supplied to the pn junction part.

2. The semiconductor optical integrated circuit according to claim 1,
wherein the pn junction part is obtained by subjecting a second semiconductor layer, which is obtained by doping a first semiconductor layer in the semiconductor substrate with an impurity at high concentration, to an anneal treatment while irradiating said second semiconductor layer with light.

3. The semiconductor optical integrated circuit according to claim 2,
wherein the semiconductor substrate is an Si substrate,
the first semiconductor layer is an n-type semiconductor layer obtained by doping said semiconductor substrate with a Group 15 element, and
the second semiconductor layer is a p-type semiconductor layer obtained by doping said first semiconductor layer with a Group 13 element.

4. The semiconductor optical integrated circuit according to claim 1,
wherein the light emitting part is provided on one end side on said pn junction part, and
a light receiving part is provided on the other end side on said pn junction part.

5. The semiconductor optical integrated circuit according to claim 2,
wherein the light emitting part is provided on one end side on said pn junction part, and
a light receiving part is provided on the other end side on said pn junction part.

6. The semiconductor optical integrated circuit according to claim 3,
wherein the light emitting part is provided on one end side on said pn junction part, and
a light receiving part is provided on the other end side on said pn junction part.
